(19) United States
(12) Patent Application Publication
(10) Pub. No.: US 2023/0361755 A1
(43) Pub. Date: Nov. 9, 2023

(54) ACOUSTIC WAVE DEVICE HAVING REDUCED SIZE

(71) Applicant: Skyworks Solutions, Inc., Irvine, CA (US)

(72) Inventor: Rei Goto, Osaka-Shi (JP)

(21) Appl. No.: 18/128,565

(22) Filed: Mar. 30, 2023

Related U.S. Application Data
(60) Provisional application No. 63/327,004, filed on Apr. 4, 2022.

(51) Int. Cl. H03H 9/205; H03H 9/145; H03H 9/25; H03H 9/02

(52) U.S. Cl. CPC H03H 9/205; H03H 9/14541; H03H 9/25; H03H 9/02574

(57) ABSTRACT

An acoustic wave device comprising a transmit filter including a plurality of surface acoustic wave resonators. Each surface acoustic wave resonator of the transmit filter including an interdigital transducer electrode comprising a first material. The acoustic wave device further comprising a receive filter including a plurality of surface acoustic wave resonators. At least a proportion of the plurality of surface acoustic wave resonators of the receive filter each including an interdigital transducer electrode comprising a second material. The density of the first material is greater than the density of the second material.

### INCORPORATION BY REFERENCE TO ANY PRIORITY APPLICATIONS

Any and all applications, if any, for which a foreign or domestic priority claim is identified in the Application Data Sheet of the present application are hereby incorporated by reference under 37 CFR 1.57.

### FIELD

### Background

Embodiments of the invention relate to acoustic wave devices.

### Description of the Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. A transmit acoustic wave filter and a receive acoustic wave filter can be arranged as a duplexer.

An acoustic wave filter can include a plurality of resonators arranged to filter a radio frequency signal. Example acoustic wave filters include surface acoustic wave (SAW) resonators and bulk acoustic wave (BAW) resonators. Designing acoustic wave devices to meet performance and size specifications with low loss can be challenging.

### SUMMARY

According to one embodiment, there is provided an acoustic wave device comprising a transmit filter including a plurality of surface acoustic wave resonators. Each surface acoustic wave resonator of the transmit filter includes an interdigital transducer electrode comprising a first material. The acoustic wave device also comprising a receive filter including a plurality of surface acoustic wave resonators. At least a proportion of the plurality of surface acoustic wave resonators of the receive filter each including an interdigital transducer electrode comprising a second material. A density of the first material is greater than a density of the second material.

An acoustic wave device may include, but is not limited to, an acoustic wave resonator, an acoustic wave filter, a duplexer, a multiplexer and an acoustic wave chip package.

Each surface acoustic wave resonator of the transmit filter may include an interdigital electrode made from the first material. At least a proportion of the plurality of surface acoustic wave resonators of the receive filter may each include an interdigital electrode made from the second material.

In one example, the receive filter may comprise a multi-mode surface acoustic wave filter including a plurality of surface acoustic wave resonators. Each acoustic wave resonator of the multi-mode surface acoustic wave filter may include an interdigital transducer electrode comprising the second material.

In one example, each of the plurality of surface acoustic wave resonators of the receive filter may comprise an interdigital transducer electrode comprising the second material.

In one example, a proportion of the plurality of surface acoustic wave resonators of the receive filter may each include an interdigital transducer electrode comprising the first material.

In one example, the density of the first material may be greater than 12.1 g/cm³, more particularly greater than 18.0 g/cm³, and yet more particularly greater than 19.0 g/cm³.

In one example, the density of the first material may be in a range from 12.2 g/cm³ to 22.6 g/cm³, more particularly in a range from 18.0 g/cm³ to 22.6 g/cm³, and yet more particularly in a range from 19.0 g/cm³ to 22.6 g/cm³.

In one example, the first material may comprise a metal or metal alloy.

In one example, the first material may be selected from one or more of platinum, iridium, gold and tungsten.

In one example, the density of the second material may be less than or equal to 12.1 g/cm³.

In one example, the density of the second material may be in a range from 8.5 g/cm³ to 12.1 g/cm³.

In one example, the second material may comprise a metal or metal alloy.

In one example, the second material may be selected from one or more of molybdenum, silver, copper and ruthenium.

In one example, each surface acoustic wave resonator of the transmit filter may include a multilayer interdigital transducer electrode. The multilayer interdigital transducer electrode may comprise a first layer of the first material. The multilayer interdigital transducer electrode may comprise a second layer comprising a third material. The third material may be aluminum.

In one example, at least a proportion of the plurality of surface acoustic wave resonators of the receive filter may each include a multilayer interdigital transducer electrode. The multilayer interdigital transducer electrode may comprise a first layer of the second material. The multilayer interdigital transducer electrode may comprise a second layer comprising a fourth material. The fourth material may be aluminum.

In one example, the interdigital transducer electrodes of the transmit and receive filters may be arranged over a piezoelectric layer.

In one example, the acoustic wave device may further include a temperature compensation layer.

In one example, the acoustic wave device may further include a multilayer piezoelectric substrate. The multilayer piezoelectric substrate may include a support substrate. The multilayer piezoelectric substrate may include a piezoelectric layer over the support substrate. The interdigital transducer electrodes of the transmit and receive filters may be arranged over the piezoelectric layer.

In one example, the acoustic wave device may further include a low velocity layer. The low velocity layer may be disposed between the support substrate and the piezoelectric layer. The low velocity layer may have an acoustic velocity lower than an acoustic velocity of the piezoelectric layer.

In one example, the surface acoustic wave resonators of the transmit filter may be arranged on a first die. The surface acoustic wave resonators of the receive filter may be arranged on a second die.

In one example, the surface acoustic wave resonators having interdigital transducer electrodes comprising the first material may be arranged on a first die. The surface acoustic wave resonators having interdigital transducer electrodes comprising the second material may be arranged on a second die.

In one example, the surface acoustic wave resonators of the transmit and receive filters are arranged on the same die.

In one example, at least one of the transmit filter or the receive filter may comprise a BAW resonator.

According to another embodiment, there is provided a filter assembly comprising a plurality of transmit filters. Each transmit filter includes a plurality of surface acoustic wave resonators. Each surface acoustic wave resonator of each transmit filter includes an interdigital transducer electrode comprising a first material. The filter assembly also comprises a plurality of receive filters. Each receive filter including a plurality of surface acoustic wave resonators. At least a proportion of the plurality of surface acoustic wave resonators of each receive filter each include an interdigital transducer electrode comprising a second material. A density of the first material is greater than a density of the second material.

In one example, the plurality of transmit filters may be co-packaged on a first die. The plurality of receive filters may be co-packaged on a second die.

In one example, the surface acoustic wave resonators having interdigital transducer electrodes comprising the first material may be arranged on a first die. The surface acoustic wave resonators having interdigital transducer electrodes comprising the second material may be arranged on a second die.

In one example, the plurality of transmit filters and the plurality of receive filters may be co-packaged on the same die.

According to another embodiment, there is provided a multiplexer comprising a plurality of duplexers. Each duplexer has its own pass band and includes a transmit filter including a plurality of surface acoustic wave resonators. Each surface acoustic wave resonator of the transmit filter includes an interdigital transducer electrode comprising a first material. Each duplexer also includes a receive filter including a plurality of surface acoustic wave resonators. At least a proportion of the plurality of surface acoustic wave resonators of the receive filter each include an interdigital transducer electrode comprising a second material. A density of the first material is greater than a density of the second material.

In one example, the transmit filters of the plurality of duplexers may be co-packaged on a first die. The receive filters of the plurality of duplexers may be co-packaged on a second die.

In one example, the surface acoustic wave resonators having interdigital transducer electrodes comprising the first material may be arranged on a first die. The surface acoustic wave resonators having interdigital transducer electrodes comprising the second material may be arranged on a second die.

In one example, the transmit filters and receive filters of the plurality of duplexers may be co-packaged on the same die.

According to another embodiment, there is provided a radio frequency module comprising a power amplifier configured to provide a radio frequency signal and a duplexer configured to filter the radio frequency signal. The duplexer includes a transmit filter including a plurality of surface acoustic wave resonators. Each surface acoustic wave resonator of the transmit filter includes an interdigital transducer electrode comprising a first material. The duplexer also includes a receive filter including a plurality of surface acoustic wave resonators. At least a proportion of the plurality of surface acoustic wave resonators of the receive filter each include an interdigital transducer electrode comprising a second material. A density of the first material is greater than a density of the second material.

According to another embodiment, there is provided a wireless communication device comprising a transmit filter including a plurality of surface acoustic wave resonators. Each surface acoustic wave resonator of the transmit filter includes an interdigital transducer electrode comprising a first material. The wireless communication device also includes a receive filter including a plurality of surface acoustic wave resonators. At least a proportion of the plurality of surface acoustic wave resonators of the receive filter each include an interdigital transducer electrode comprising a second material. A density of the first material is greater than a density of the second material.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1A is a schematic diagram of an acoustic wave device having molybdenum interdigital transducer electrodes co-packaged on the same die;

FIG. 1B is a schematic diagram of an acoustic wave device having tungsten interdigital transducer electrodes co-packaged on the same die;

FIG. 1C is a schematic diagram of an acoustic wave device according to an embodiment, in which molybdenum interdigital transducer electrodes are co-packaged on a first die and tungsten interdigital transducer electrodes are co-packaged on a second die;

FIG. 2 is a schematic diagram of an acoustic wave device according to an embodiment in which molybdenum and tungsten interdigital transducer electrodes are co-packaged on the same die;

FIG. 3A is a circuit diagram of the acoustic wave device of FIG. 1B;

FIG. 3B is a circuit diagram of the acoustic wave device of FIG. 1C according to an embodiment;

FIG. 3C is a circuit diagram of an acoustic wave device according to another embodiment;

FIG. 4 is a graph showing simulated transmission characteristics of molybdenum and tungsten interdigital transducer electrodes in an acoustic wave device;

FIG. 5 is a graph showing simulated reflection coefficients of molybdenum and tungsten interdigital transducer electrodes in an acoustic wave device;

FIGS. 6A to 6G each show, in an upper part of the figure, a transverse cross-section of an acoustic wave device according to an embodiment and, in a lower part of the figure, a plan view of an example geometry of the interdigital transducer electrode used in the acoustic wave device;

FIGS. 7A and 7B each show a partial longitudinal cross-section of an acoustic wave device according to an embodiment;

FIGS. 8A to 8D show transverse cross-sections of an acoustic wave device according to another embodiment;

FIG. 9 is a schematic block diagram of a radio frequency module that includes an antenna switch and acoustic wave devices in accordance with one or more embodiments;

FIG. 10 is a schematic block diagram of a radio frequency module that includes a power amplifier, a radio frequency switch, and acoustic wave devices in accordance with one or more embodiments;

FIG. 11 is a schematic block diagram of a radio frequency module that includes a power amplifier, a radio frequency switch, an acoustic wave device in accordance with one or more embodiments, and an antenna switch;

FIG. 12 is a schematic block diagram of a radio frequency module that includes acoustic wave devices according to one or more embodiments; and

FIG. 13 is a schematic block diagram of a wireless communication device that includes acoustic wave devices according to one or more embodiments.

### DETAILED DESCRIPTION

Aspects and embodiments described herein are directed to an acoustic wave device that uses a high density material, such as tungsten, in the interdigital transducer electrodes of the transmit filter and a lower density material, such as molybdenum, for at least a proportion of the interdigital transducer electrodes of the receive filter. Higher density materials help to reduce the size of interdigital transducer electrodes because they produce lower velocity acoustic waves and have a higher reflection coefficient. Transmit filters generally occupy more area than receive filters. Therefore, by reducing the size of the interdigital transducer electrodes of the transmit filter, a significant reduction in the size of the transmit filter can be realized. However, the higher reflection coefficient of higher density materials can make receive filter design more difficult and reduce the performance of the receive filter, in particular, a receive filter including an acoustically coupled filter such as a coupled resonator filter (CRF) or a multimode SAW filter such as a Double Mode SAW (DMS) filter. Lower density materials have lower reflection coefficients and therefore help to achieve good electrical performance of the receive filter including a CRF or DMS filter. By using a high density material in the interdigital transducer electrodes of the transmit filter and a lower density material for at least a proportion of the interdigital transducer electrodes of the receive filter, can reduce the overall size of the acoustic wave device and provide a good balance between size and performance. It has also been found that using a high density material in a proportion of the interdigital transducer electrodes of the receive filter can help to improve the reflection coefficient characteristics of the antenna port.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

There is a strong demand to reduce the size of acoustic wave devices such as acoustic wave filters. However, meeting this demand without degrading performance is challenging. One possible solution for reducing the area occupied by acoustic wave filters is to co-package multiple filters on to a common die or substrate.

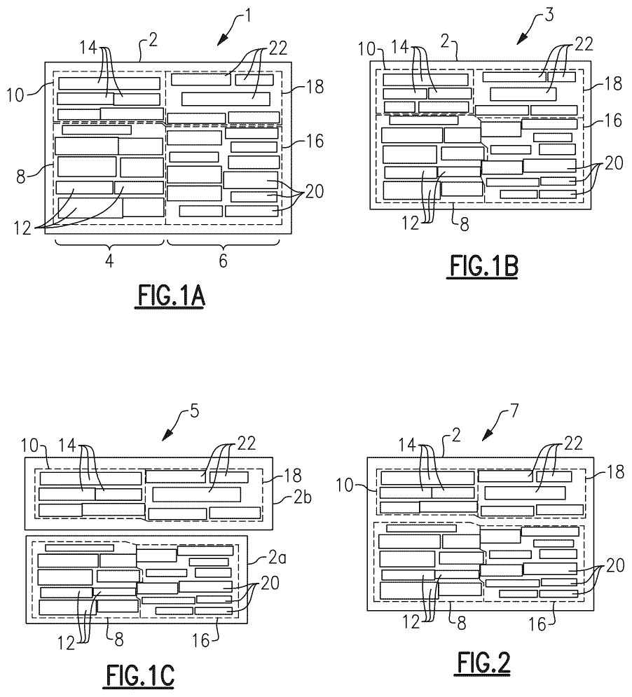

FIG. 1A shows a schematic diagram of an acoustic wave device 1 in which multiple filters have been co-packaged on to a common die 2. The acoustic wave device 1 of FIG. 1A is part of a multiplexer comprising two duplexers 4 and 6 for two different frequency bands. A first duplexer 4 includes a first transmit filter 8 and a first receive filter 10 for a first frequency band A. The first transmit filter 8 includes surface acoustic wave (SAW) resonators 12 and the first receive filter 10 includes SAW resonators 14. A second duplexer 6 includes a second transmit filter 16 and a second receive filter 18 for a second frequency band B. The second transmit filter 16 includes SAW resonators 20 and the second receive filter 18 includes SAW resonators 22. Each of the resonators 12, 14, 20 and 22 includes a interdigital transducer electrode (not shown).

In the acoustic wave device 1 of FIG. 1A all of the interdigital transducer electrodes comprise molybdenum, which has a relatively moderate density of 10.2 g/cm³. Due to their density, the molybdenum interdigital transducer electrodes also have a moderate reflection coefficient and therefore the resonators 12, 14, 20 and 22 are larger than if higher density materials had been used. Consequently, the overall size of the acoustic wave device 1 is larger. However, the moderate density of molybdenum results in good electrical performance of the receive filter with fewer spurious responses.

The acoustic wave device 1 of FIG. 1A is a temperature compensated SAW (TCSAW) device comprising TCSAW filters. A temperature compensated SAW filter is a filter which has been adapted to have improved thermal stability. The center frequency of a SAW filter can vary with changes in temperature caused, for example, by heat generated during operation. A temperature compensated SAW filter seeks to minimize variations in the center frequency of the filter as temperature changes.

FIG. 1B shows a schematic diagram of another acoustic wave device 3. The acoustic wave device 3 of FIG. 1B is identical to that of FIG. 1A with the exception that all of the interdigital transducer electrodes of the resonators 12, 14, 20 and 22 comprise tungsten, which has a relatively high density of 19.3 g/cm³. The higher density of tungsten interdigital transducer electrodes helps to produce a lower velocity acoustic wave and a higher reflection coefficient compared to molybdenum interdigital transducer electrodes, which means that the interdigital transducer electrodes, and consequently the resonators 12, 14, 20 and 22 of the acoustic wave device 3 of FIG. 1B are smaller than those of acoustic wave device 1 of FIG. 1A. This reduces the overall size of the acoustic wave device 3 considerably. However, the higher reflection coefficient of tungsten makes the design of the receive filters 10 and 18 difficult. In particular, it can be detrimental to the performance of a multi-mode SAW filter, which typically forms part of the receive filters 10 and 18, as discussed further below.

FIG. 1C is a schematic diagram of an acoustic wave device 5 according to an embodiment. The acoustic wave device 5 of FIG. 1C is also part of a multiplexer and includes components corresponding the devices of FIGS. 1A and 1B. However, in the acoustic wave device 5 of FIG. 1C, the interdigital transducer electrodes of the resonators 12 and 20 of the transmit filters 8 and 16 comprise tungsten and the interdigital transducer electrodes of the resonators 14 and 22 of the receive filters 10 and 18 comprise molybdenum. Furthermore, the transmit filters 8 and 16 are co-packaged on a first die 2a and the receive filters 10 and 18 are co-packaged on a second die 2b. The acoustic wave device 5 is also a TCSAW device.

The arrangement of the acoustic wave device 5 of FIG. 1C has the benefit of reducing the overall size of the device compared to the acoustic wave device 1 of FIG. 1A, in which all interdigital transducer electrodes comprise molybdenum. This is achieved through the use of reduced size tungsten interdigital transducer electrodes in the transmit filters 8 and 16. Given that the transmit filters are generally larger than the receive filters, a significant reduction in the overall size of the acoustic wave device 5 is provided. A further benefit of the acoustic wave device 5 of FIG. 1C is that

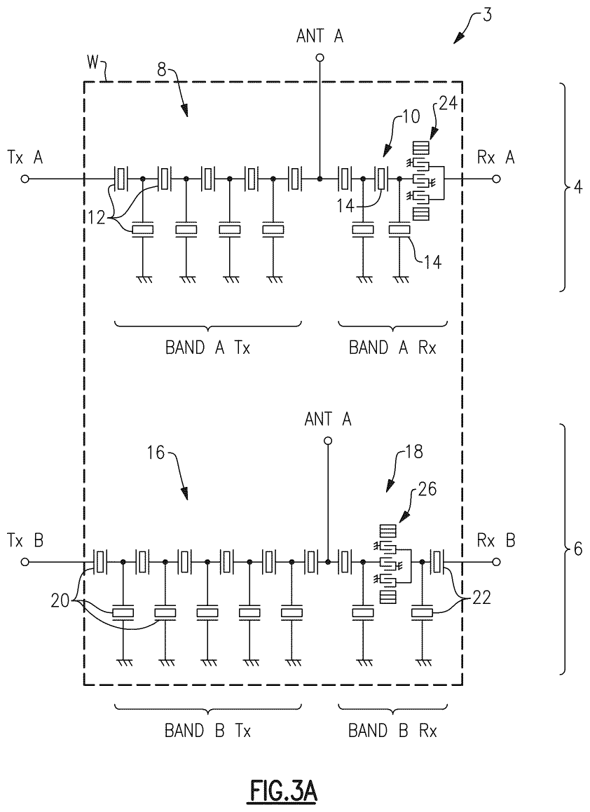

FIG. 2 is a schematic diagram of an acoustic wave device 7 according to another embodiment. The acoustic wave device 7 of FIG. 2 is identical to the acoustic wave device 5 of FIG. 1C with the exception that the transmit filters 8 and 16 and the receive filters 10 and 18 are co-packaged on a common die 2. This can help to achieve a further reduction in the size of the device.

Whilst the acoustic wave devices 5 and 7 of FIGS. 1C and 2 respectively are shown with two duplexers, it will be appreciated that the devices could implement are larger number of duplexers to filter a large number of frequency bands. In addition, it will be appreciated that the material of the interdigital transducer electrodes of the transmit filters is not limited to tungsten but that other materials, in particular, other metals, could be used. For example, platinum, gold and iridium show similar benefits.

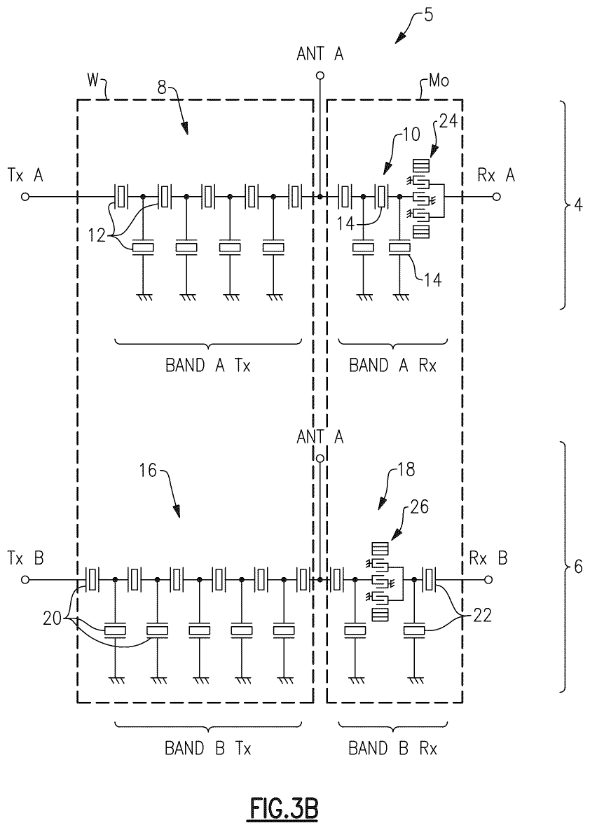

FIG. 3A is a circuit diagram of the acoustic wave device 3 of FIG. 1B. The acoustic wave device 3 is part of a multiplexer and comprises two duplexers 4 and 6 for two different frequency bands. A first duplexer 4 includes a first transmit filter 8 and a first receive filter 10 for a first frequency band A. The first transmit filter 8 and first receive filter 10 are coupled to each other at an antenna node Ant A. The first transmit filter 8 can filter a radio frequency signal provided at a first transmit input node Tx A and provide a filtered radio frequency transmit signal to the antenna node Ant A. The first receive filter 10 can filter a radio frequency signal received at the antenna node Ant A and provide a radio frequency receive signal at a first receive output node Rx A.

The first transmit filter 8 includes SAW resonators 12 and the first receive filter 10 includes SAW resonators 14. The SAW resonators 12 of the first transmit filter 8 and the SAW resonators 14 of the first receive filter 10 are both arranged in a ladder configuration to filter the radio frequency signal. The first receive filter 10 includes a multi-mode or dual mode SAW filter 24. A multi-mode SAW filter is a type of surface acoustic wave filter. Multi-mode SAW filters include a plurality of resonators each comprising an interdigital transducer electrode that are longitudinally coupled to each other and positioned between acoustic reflectors. Some multi-mode SAW filters are referred to as dual mode SAW (DMS) filters, although such filters may have more than two modes.

A second duplexer 6 of the acoustic wave device 3 includes a second transmit filter 16 and a second receive filter 18 for a second frequency band B. The second transmit filter 16 and second receive filter 18 are also coupled to each other at an antenna node Ant A. The second transmit filter 16 can filter a radio frequency signal provided at a second transmit input node Tx B and provide a filtered radio frequency transmit signal to the antenna node Ant A. The second receive filter 18 can filter a radio frequency signal received at the antenna node Ant A and provide a radio frequency receive signal at a second receive output node Rx B.

The second transmit filter 16 includes SAW resonators 20 and the second receive filter 18 includes SAW resonators 22. The SAW resonators 20 of the second transmit filter 16 and the SAW resonators 22 of the second receive filter 18 are both arranged in a ladder configuration to filter the radio frequency signal. The second receive filter 18 includes DMS filter 26. In the circuit of FIG. 3A all of the interdigital transducer electrodes (not shown) of the resonators 12, 14, 20 and 22 and the resonators of the DMS filters 24 and 26, that is, the resonators enclosed by box W in FIG. 3A, comprise tungsten. It will be appreciated that the acoustic wave device 3 of FIG. 3A may also comprise a switch (not shown) for switching between frequency bands.

FIG. 3B is a circuit diagram of the acoustic wave device 5 of FIG. 1C according to one embodiment. The acoustic wave device 5 of FIG. 3B is also part of a multiplexer and has the same circuit layout as the acoustic wave device 3 of FIG. 3A. However, in the acoustic wave device 5 of FIG. 3B, the interdigital transducer electrodes (not shown) of the resonators 12 and 20 of the transmit filters 8 and 16, that is, the resonators enclosed by box W in FIG. 3B, comprise tungsten. The interdigital transducer electrodes of the resonators 14 and 22 of the receive filters 10 and 18, including the resonators of the DMS filters 24 and 26, that is, the resonators enclosed by box Mo in FIG. 3B, comprise molybdenum.

FIG. 3C is a circuit diagram of an acoustic wave device 9 according to another embodiment. The acoustic wave device 9 of FIG. 3C is also part of a multiplexer and has the same circuit layout as the acoustic wave devices of FIGS. 3A and 3C. However, in the acoustic wave device 9 of FIG. 3C, the interdigital transducer electrodes (not shown) of the resonators 12 and 20 of the transmit filters 8 and 16 and a proportion of the resonators 14 and 22 of the receive filters 10 and 18, that is, the resonators enclosed by box W in FIG. 3C, comprise tungsten. As can be seen in FIG. 3C, two of the resonators 14a and 14b of the first receive filter 10 nearest the antenna port Ant A and two of the resonators 22a and 22b of the second receive filter 18 nearest the antenna port Ant A comprise tungsten and are enclosed by box W. The interdigital transducer electrodes of the remaining resonators 14 and 22 of the receive filters 10 and 18, including the resonators of the DMS filters 24 and 26, that is, the resonators enclosed by box Mo in FIG. 3C, comprise molybdenum. In this embodiment the tungsten resonators enclosed by box W may be arranged on a first die and the molybdenum resonators enclosed by box Mo may be arranged on a second die. In this case, the first die will contain the proportion of receive filter resonators that comprise tungsten, which will result in those resonators being smaller than if they comprised molybdenum and will result in further reductions in the overall size of the device. This arrangement has also been found to improve the reflection coefficient characteristics of the antenna port Ant A. the improved reflection coefficient can make this arrangement more suitable for filter ganging or banking. In another embodiment, the tungsten and molybdenum resonators may be arranged on a common die, which will also achieve reductions in the overall size of the device for similar reasons.

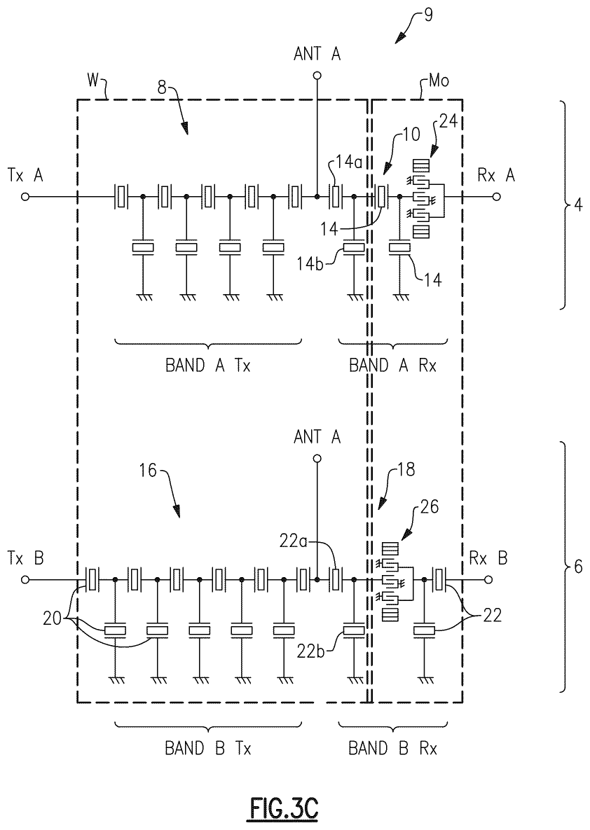

FIG. 4 shows a graph of simulated transmission characteristics of molybdenum and tungsten interdigital transducer electrodes in an acoustic wave device over a certain frequency range. In particular, FIG. 4 shows the transmission characteristics of molybdenum and tungsten interdigital transducer electrodes in a three interdigital transducer electrode DMS filter, such as the DMS filters 24 and 26 shown in FIGS. 3A to 3C. The traces on the graph represented by Tr1 and Tr2 each show characteristics for both molybdenum interdigital transducer electrodes (Mo IDT) and tungsten interdigital transducer electrodes (W IDT). Tr1 shows the characteristics at 5 dB per division and Tr2 shows the same characteristics at 1 dB per division. As can be seen from Tr1 of the graph of FIG. 4, the tungsten interdigital transducer electrodes exhibit a spike or spurious response X on the low frequency side of the passband due to their higher reflection coefficient. Such spurious responses make it difficult to obtain a steep sided attenuation at the edges of the receive filter passband if tungsten interdigital transducer electrodes are used.

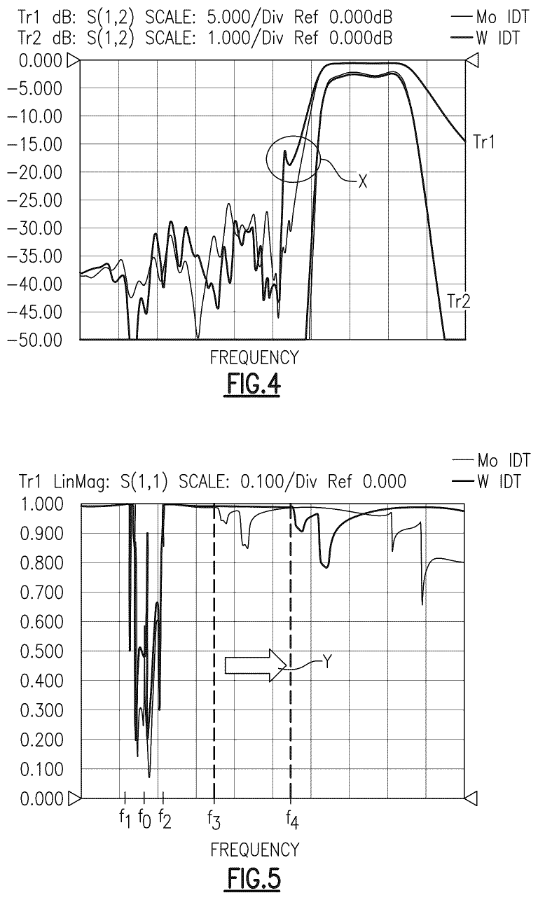

FIG. 5 is a graph showing simulated electric signal reflection coefficients in an acoustic wave device such as the acoustic wave devices shown in FIGS. 3A to 3C with molybdenum and tungsten interdigital transducer electrodes. The graph shows a passband between frequencies f₁ and f₂ either side of a resonant frequency f₀ where the reflection coefficient drops significantly to allow a desired frequency band to pass through a filter. Either side of the passband the reflection coefficient is relatively high, that is, near 1.0, to keep unwanted frequencies from passing through the filter. The molybdenum interdigital transducer electrode (Mo IDT) has two noticeable degradations in reflection coefficient above the passband frequencies which start at frequency f₃. The tungsten interdigital transducer electrode (W IDT) also has two noticeable degradations in reflection coefficient above the passband frequencies which start at frequency f₄. However, the degradations in the reflection coefficient of the W IDT curve occur at higher frequencies, that is, in the direction of arrow Y in the graph of FIG. 5, and further from the passband. Consequently, W IDTs have a between reflection coefficient range than Mo IDTs and the degradations in the reflection coefficient of the W IDT are less likely to interfere with the passband.

As mentioned above, the reflection coefficient of the antenna port Ant A is important for filter ganging or banking. The reflection coefficient of the antenna port is largely determined by the characteristics of the resonators nearest to the antenna port Ant A. Therefore, using tungsten interdigital transducer electrodes in the resonators nearest to the antenna port Ant A can be beneficial for filter ganging because any degradations in the reflection coefficient are more removed from the passband. Accordingly, the acoustic wave device 9 of FIG. 3C, which has tungsten interdigital transducer electrodes either side of the antenna port Ant A will exhibit improved reflection coefficient at the antenna port Ant A and is particularly suitable for filter ganging.

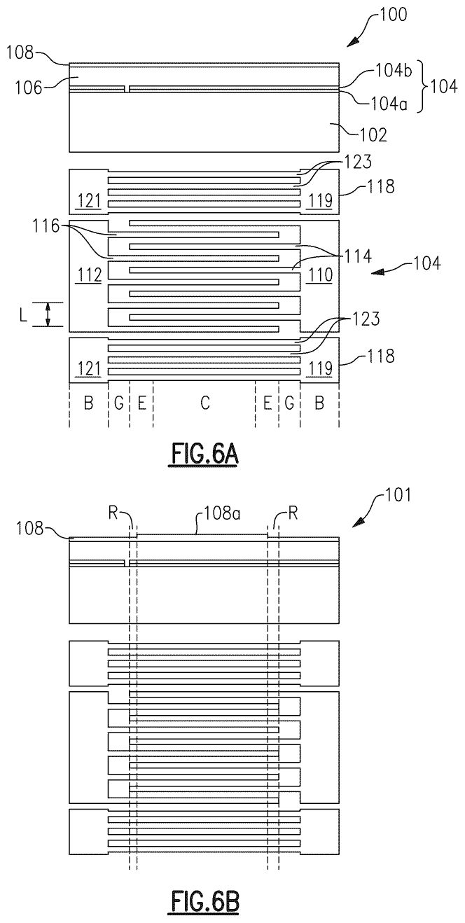

FIGS. 6A to 6G each show, in an upper part of the figure, a side cross-section of an acoustic wave resonator according to an embodiment and, in a lower part of the figure, a plan view of an example geometry of the interdigital transducer electrode used in the acoustic wave resonator. The configuration of any one of the resonators illustrated in FIGS. 6A to 6G may be applied to any of the resonators illustrated in FIGS. 1 to 3C described above.

Referring to the upper part of FIG. 6A, an acoustic wave resonator 100 is shown in transverse cross-section and includes a piezoelectric substrate, for example, a lithium tantalate (LiTaO₃) or lithium niobate (LiNbO₃) substrate 102, over which are arranged interdigital transducer (IDT) electrodes 104. The IDT electrodes 104 excite a main acoustic wave having a wavelength L along a surface of the piezoelectric substrate 102. The acoustic wave resonator 100 may therefore be referred to as a SAW resonator.

The IDT electrodes 104 are layered electrodes including a first or lower layer 104a of a first material which can be either a moderately dense material such as molybdenum (Mo), copper (Cu), ruthenium (Ru) or silver (Ag) or a higher density material such as tungsten (W), platinum (Pt), Iridium (IR) or gold (Au). The IDT electrodes 104 may further include a second or upper layer 104b of a highly conductive but low-density material, for example, aluminum (Al). The moderate or high density first layer 104a may reduce the acoustic velocity of acoustic waves travelling through the device which may allow the fingers of the IDT electrode to be spaced more closely for a given operating frequency and allow the SAW device to be reduced in size as compared to a similar device utilizing less dense IDT electrodes. The low density second layer 104b may have a higher conductivity than the first layer 104a to provide the IDT electrode with a lower overall resistivity than an electrode including only the denser first layer 104a.

A temperature compensation layer 106 comprising, for example, silicon dioxide (SiO₂) is arranged over the IDT electrode 104. The temperature compensation layer 106 may have a negative temperature coefficient of frequency, which helps to offset the positive temperature coefficient of frequency of the piezoelectric substrate 102 and reduce the change in frequency response of the SAW resonator 100 with changes in temperature. A SAW device with a layer of SiO₂ over the IDT electrodes may thus be referred to as a temperature-compensated SAW device, or TCSAW. The temperature compensation layer 106 is not limited to a layer of pure silicon dioxide (SiO₂) but can include fluorine (F) doped SiO₂ or other doped SiO₂ materials.

A passivation layer 108 is arranged over the temperature compensation layer 106 and includes a material having high impedance and high acoustic wave velocity, for example, silicon nitride (SiN) or aluminum nitride (AlN) and silicon oxynitride (SiON). The passivation layer helps to protect the acoustic wave resonator and has other beneficial properties as discussed below.

Referring to the lower part of FIG. 6A, IDT electrodes 104 include a first bus bar electrode 110 and a second bus bar electrode 112 facing first bus bar electrode 110. The IDT electrodes 104 further include first electrode fingers 114 extending from the first bus bar electrode 110 toward the second bus bar electrode 112, and second electrode fingers 116 extending from the second bus bar electrode 112 toward the first bus bar electrode 110. The first electrode fingers 114 and second electrode fingers 116 have a pitch L and are configured to generate a surface acoustic wave having a wavelength L. The IDT electrodes 104 are sandwiched between two reflector electrodes 118. The reflector electrodes 118 reflect the main acoustic wave back and forth through the IDT electrodes 104. The main acoustic wave of the acoustic wave resonator 100 travels perpendicular to the direction of extension of the electrode fingers 114 and 116. The reflector electrodes 118 (also referred to as reflector gratings) each include a first reflector bus bar electrode 119 and a second reflector bus bar electrode 121 and reflector fingers 123 extending between and electrically coupling the first bus bar electrode 119 and the second bus bar electrode 121.

As illustrated in FIG. 6A, regions along lengths of the IDT electrodes 104 of the acoustic wave resonator 100, may be characterized as busbar regions “B” including the busbar portions of the IDT electrodes, gap regions “G” between the busbar of a first IDT electrode and the ends of the fingers of a second opposing IDT electrode, edge regions “E” including end portions of the IDT electrode fingers, and a center region “C” sandwiched between the edge regions. These regions will be referred to when discussing FIGS. 6B to 6G below.

Referring to the upper part of FIG. 6B, another acoustic wave resonator 101 is shown in transverse cross-section, which has the same configuration as the acoustic wave resonator 100 of FIG. 6A with the exception that the passivation layer 108 includes a thicker portion 108a disposed in the center region C compared to the other regions B, G, and E. This reduced thickness portion of the passivation layer 108 in regions B, G and E may be formed by depositing a layer of SiN or AlN with a uniform thickness on the temperature compensation layer 106 and then etching away areas of the SiN or AlN outside of the center region. The thicker portion 108a of SiN or AlN over the IDT electrodes in the center region C helps to confine acoustic waves to the center region C because SiN and AlN are both high acoustic wave velocity materials. The regions R of reduced thickness in the edge regions E help to slow down the propagation of the acoustic wave in regions R and G and reduce the amount of acoustic energy that travels outside of the center region C in a direction perpendicular to that of the propagation direction of the main acoustic wave. The escape of acoustic energy in a perpendicular direction may cause transverse mode spurious signals in the frequency response of the acoustic wave resonator 101. As discussed above, the main acoustic wave of a surface acoustic wave resonator travels perpendicular to the direction of extension of the electrode fingers of the IDT electrode and the transverse mode spurious signals may be caused by acoustic waves travelling parallel to the direction of extension of the electrode fingers. Suppressing transverse modes to improve the performance of an acoustic wave resonator is generally desirable. Referring to the lower part of FIG. 6B, the IDT electrodes 104 of acoustic wave resonator 101 has an identical configuration or geometry to that of FIG. 6A.

Referring to the upper part of FIG. 6C, the cross-sectional structure of another embodiment of acoustic wave resonator 103 is identical to that of FIG. 6B. However, as illustrated in the lower part of FIG. 6C, the configuration or geometry of the IDT electrodes 104 of acoustic wave resonator 103 is different to the foregoing embodiments in that the electrode fingers 114 and 116 of the IDT electrodes include thickened portions or “hammers” 120 in the edge regions E. The hammers 120 increase the width or duty factor of the IDT electrodes 104 in the edge regions E which helps to reduce the acoustic velocity in the edge regions E and suppress transverse modes. Therefore, the acoustic wave resonator of FIG. 6C helps to reduce transverse modes by both a reduced thickness of passivation layer 108 in regions R and increase duty factor of the IDT electrodes in regions E. A further benefit of the hammers 120 is that they reduce the spacing between the electrode fingers 114 and 116 of IDT electrodes 104 which helps to reduce the capacitance of the IDT electrode 104, which allows the size of the IDT electrode to be reduced. As can be seen from the lower part of FIG. 6C, the reflector electrodes 118 also include hammers 120 for similar reasons to the IDT electrodes 104.

Referring to the upper part of FIG. 6D, the cross-sectional structure of another embodiment of acoustic wave resonator 105 is identical to that of FIG. 6C. Referring to the lower part of FIG. 6D, the configuration or geometry of the IDT electrodes 104 of acoustic wave resonator 105 is identical to that of FIG. 6C with the exception that the IDT electrodes of acoustic wave resonator 105 include mini bus bar electrodes 122 in the gap regions G. The mini bus bar electrodes 122 are coupled to the electrode fingers 114 and 116 and extend perpendicular to their respective electrode finger 114, 116 toward an adjacent electrode finger 114, 116 in the gap regions G. The mini bus bar electrodes 122 help to suppress higher order transverse modes. As can be seen from the lower part of FIG. 6D, the reflector electrodes 118 also include mini bus bar electrodes 122.

Referring to the upper part of FIG. 6E, the cross-sectional structure of another embodiment of acoustic wave resonator 107 is identical to that of FIG. 6D. Referring to the lower part of FIG. 6E, the configuration or geometry of the IDT electrodes 104 of acoustic wave resonator 107 is identical to that of FIG. 6D with the exception that the mini bus bar electrodes 122 extending continuously in the space between adjacent electrode fingers 114 and 116 to bridge the space. This arrangement helps to suppress transverse modes and transverse mode separation. As can be seen from FIG. 6D, the reflector electrodes 118 also include mini bus bars 122. As can be seen from FIG. 6E, the reflector electrodes 118 also include mini bus bar electrodes 122 extending continuously between reflector fingers 123.

Referring to the upper part of FIG. 6F, another acoustic wave resonator 109 is shown in transverse cross-section, which has the same configuration as the acoustic wave resonator 100 of FIG. 6A with the exception that the acoustic wave resonator 109 includes a mass loading strip 124 of high density material extending along the length of the acoustic wave resonator 109 in the direction of acoustic wave propagation in each of the edge regions E, that is, on either side of the central region C. The mass loading strips 124 may comprise the same material as the first layer 104a of the IDT electrode 104, for example, the mass loading strips 124 may comprise tungsten (W), platinum (Pt), Iridium (IR) or gold (Au). The mass loading strips 124 are embedded in the temperature compensation layer 106 to avoid electrically shorting the IDT electrodes 104. The mass loading strips 124 decrease the acoustic velocity in the edge regions E relative to the center region C which aids in keeping the acoustic waves generated during operation of the acoustic wave resonator within the center region C. Referring to the lower part of FIG. 6F, the IDT electrodes 104 of acoustic wave resonator 109 have an identical geometry to that of FIG. 6A.

Referring to the upper part of FIG. 6G, another acoustic wave resonator 111 is shown in transverse cross-section, which has the a similar configuration to the acoustic wave resonator 109 of FIG. 6F with the exception that the acoustic wave resonator 111 includes mass loading sections 126 of high density material at the ends of each of the electrode fingers 114 and 116 in each of the edge regions E. The mass loading sections 126 may comprise the same material as the first layer 104a of the IDT electrode 104, for example, the mass loading sections 126 may comprise tungsten (W), platinum (Pt), Iridium (IR) or gold (Au). Given that the mass loading sections 126 are in contact with the IDT electrodes 104, they cannot extend along the length of the acoustic wave resonator because this would short the electrodes. Instead, the mass loading sections 126 are just provided at the ends of each of the electrode fingers 114 and 116. Referring to the lower part of FIG. 6G, the IDT electrodes 104 of acoustic wave resonator 111 have an identical geometry to that of FIG. 6A.

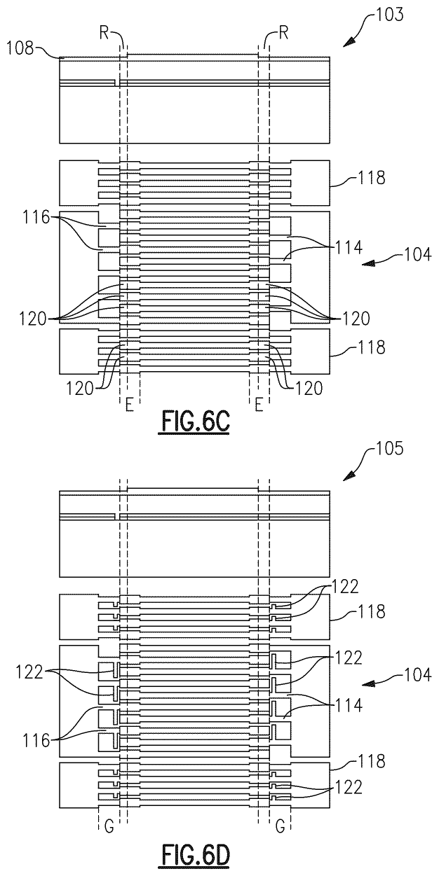

FIGS. 7A and 7B each show a partial longitudinal cross-section of an acoustic wave device according to an embodiment. Referring to FIG. 7A, this shows a TCSAW resonator 113 having an identical cross-sectional structure to the acoustic wave resonator 100 of FIG. 6A. The TCSAW resonator 113 comprises a piezoelectric substrate 102 over which are arranged IDT electrodes 104. The IDT electrodes 104 include first electrode fingers 114 and second electrode fingers 116, which are interdigitated with the first electrode fingers 114. The first electrode fingers 114 and second electrode fingers 116 have a pitch L and are configured to generate a surface acoustic wave having a wavelength L. It will be appreciated that only two pairs of first electrode fingers 114 and second electrode fingers 116 are shown in FIG. 7A but in practice the IDT electrodes 104 will include a greater number of electrode fingers. The TCSAW resonator 113 further comprises a temperature compensation layer 106 and a passivation layer 108. The thickness of the temperature compensation layer 106 can be a proportion of the wavelength L. For example, the thickness of the temperature compensation layer 106 can be in a range from 0.1L to 0.4L. The thickness of the passivation layer 108 can be in a range from 5 nanometers to 100 nanometers. In an embodiment of the TCSAW resonator 113 of FIG. 7A, the piezoelectric layer 102 can be lithium niobate (LiNbO₃), the temperature compensation layer 106 can be silicon dioxide (SiO₂) and the passivation layer 108 can be silicon nitride (SiN) or silicon oxynitride (SiON).

The IDT electrodes 104 of the TCSAW resonator 113 shown in FIG. 7A are layered electrodes including a first or lower layer 104a and a second or upper layer 104b. The first layer 104a comprises a moderately dense material such as molybdenum (Mo), copper (Cu), ruthenium (Ru) or silver (Ag) and the second or upper layer 104b comprises a highly conductive but low-density material, for example, aluminum (Al). The thickness of the first 104a and second 104b layers can be a proportion of the wavelength L. For example, the thickness of the first layer 104a can be in a range from 0.02L to 0.06L. The thickness of the second layer 104b can be in a range from 0.02L to 0.06L. In an embodiment of the acoustic wave resonator 100 of FIG. 7A, the first layer 104a comprises molybdenum (Mo) and the second layer 104b comprises aluminum (Al).

Referring to FIG. 7B, this shows a TCSAW resonator 115 having an identical cross-sectional structure to the TCSAW resonator 113 of FIG. 7A with the exception that the first layer 104a comprises a higher density material such as tungsten (W), platinum (Pt), Iridium (IR) or gold (Au). The thickness of the first layer 104a can be in a range from 0.02L to 0.09L. In an embodiment of the TCSAW resonator 1115 of FIG. 7B, the first layer 104a comprises tungsten (W) and the second layer 104b comprises aluminum (Al). Compared to the TCSAW resonator 113 of FIG. 7A, the higher density first layer 104a of the IDT electrodes 104 of the TCSAW resonator 115 of FIG. 7B reduces the acoustic velocity of acoustic waves travelling through the resonator which may allow the fingers of the IDT electrodes 104 to be spaced more closely for a given operating frequency and allow the TCSAW resonator 115 to be reduced in size. The configuration of either of the resonators illustrated in FIGS. 7A and 7B may be applied as appropriate to the resonators illustrated in FIGS. 1 to 3C described above.

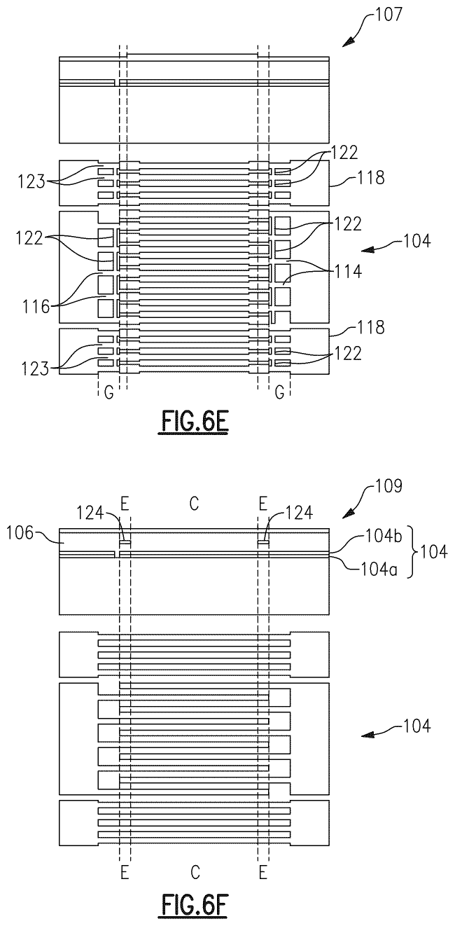

In addition to the TCSAW resonators described above with respect to FIGS. 6A to 7B, acoustic wave devices according to the present disclosure can also have a multilayer piezoelectric substrate structure which may include a thinner piezoelectric layer arranged over a support substrate in combination with one or more additional layers, as illustrated in FIGS. 8A to 8D. The configuration of any one of the resonators illustrated in FIGS. 8A to 8D may be applied to any of the resonators illustrated in FIGS. 1 to 3C described above.

FIG. 8A shows a cross-section of an acoustic wave resonator 200 according to another embodiment. The acoustic wave resonator 200 includes a piezoelectric layer, for example, a lithium tantalate (LiTaO₃) or lithium niobate (LiNbO₃) layer 202, over which are arranged interdigital transducer (IDT) electrodes 204. The IDT electrodes 204 excite a main acoustic wave along a surface of the piezoelectric layer 202. The acoustic wave resonator 200 may therefore be referred to as a SAW resonator.

Similar to the IDT electrodes 104 of the acoustic wave resonators of FIGS. 6A to 6G, the IDT electrodes 204 of the acoustic wave resonator 200 of FIG. 8A are layered electrodes including a first or lower layer 204a of a first material which can be either a moderately dense material such as molybdenum (Mo), copper (Cu), ruthenium (Ru) or silver (Ag) or a higher density material such as tungsten (W), platinum (Pt), Iridium (IR) or gold (Au). The IDT electrodes 204 may further include a second or upper layer 204b of a highly conductive but low-density material, for example, aluminum (Al).

The piezoelectric layer 202 is arranged over a support substrate 208. The support substrate 208 can be a silicon substrate, a quartz substrate, a sapphire substrate, a polycrystalline spinel substrate, or any other suitable carrier substrate. A low velocity layer 206 is arranged between the piezoelectric layer 202 and the support substrate 208. The low velocity layer 206 can include any suitable material that has an acoustic velocity lower than an acoustic velocity of the piezoelectric layer 202. For example, the low velocity layer 206 can be a silicon oxide layer such as a silicon dioxide layer. The low velocity layer 206 may also function as a temperature compensation layer. A passivation layer 210 is arranged over the IDT electrodes 204 and includes a material having high impedance and high acoustic wave velocity, for example, silicon nitride (SiN) or aluminum nitride (AlN).

FIG. 8B shows a cross-section of an acoustic wave resonator 201 according to another embodiment. The acoustic wave resonator 201 of FIG. 8B is identical to that of FIG. 8A with the exception that a high velocity layer 212 is arranged between the low velocity layer 206 and the support substrate 208. The high velocity layer 212 can include any suitable material that has an acoustic velocity higher than an acoustic velocity of the piezoelectric layer 202. For example, the high velocity layer 212 may include one or more of a silicon layer, a silicon nitride layer, an aluminum nitride layer, a diamond layer, a quartz layer, or a spinel layer. The high velocity layer 212 may be made from the same material a the passivation layer 210.

FIG. 8C shows a cross-section of an acoustic wave resonator 203 according to another embodiment. The acoustic wave resonator 203 of FIG. 8C is identical to that of FIG. 8A with the exception that a temperature compensation layer 214 is arranged over the IDT electrodes 204, that is, between the IDT electrodes 204 and the passivation layer 210. The temperature compensation layer 214 may include any suitable temperature compensating material, for example, silicon dioxide (SiO₂). The temperature compensation layer 214 may have a negative temperature coefficient of frequency, which helps to offset the positive temperature coefficient of frequency of the piezoelectric substrate 202 and reduce the change in frequency response of the acoustic wave resonator 203 with changes in temperature.

FIG. 8D shows a cross-section of an acoustic wave resonator 205 according to another embodiment. The acoustic wave resonator 205 of FIG. 8D is identical to that of FIG. 8C with the exception that a high velocity layer 212 is arranged between the low velocity layer 206 and the support substrate 208. The high velocity layer 212 can be the same as the high velocity layer 212 used in the acoustic wave resonator 201 of FIG. 8B.

It will be appreciated that the acoustic wave devices of FIGS. 7A, 7B and 8A to 8D could have any of the example IDT electrode geometries shown in the lower parts of FIGS. 6A to 6G.

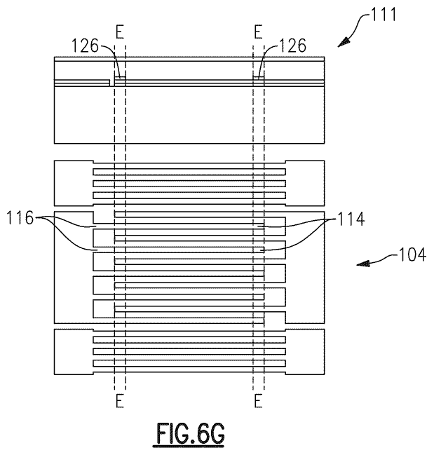

The acoustic wave filters, duplexers, and multiplexers discussed herein can be implemented in a variety of packaged modules. Some example packaged modules will now be discussed in which any suitable principles and advantages of the acoustic wave filters, duplexers and/or other multiplexers discussed herein can be implemented. The example packaged modules can include a package that encloses the illustrated circuit elements. The illustrated circuit elements can be disposed on a common packaging substrate. The packaging substrate can be a laminate substrate, for example. FIGS. 9, 10, and 11 are schematic block diagrams of illustrative packaged modules according to certain embodiments. Any suitable combination of features of these modules can be implemented with each other.

FIG. 9 is a schematic block diagram of a module 300 that includes duplexers 302A to 302N and an antenna switch 304. Any suitable number of duplexers 302A to 302N can be implemented. The antenna switch 304 can have a number of throws corresponding to the number of duplexers 302A to 302N. The antenna switch 304 can electrically couple a selected duplexer to an antenna port of the module 300. One or more of the duplexers 302A to 302N can include a transmit filter TX₁-TX_{N} and a receive filter RX₁-RX_{N} in accordance with any suitable principles and advantages discussed herein.

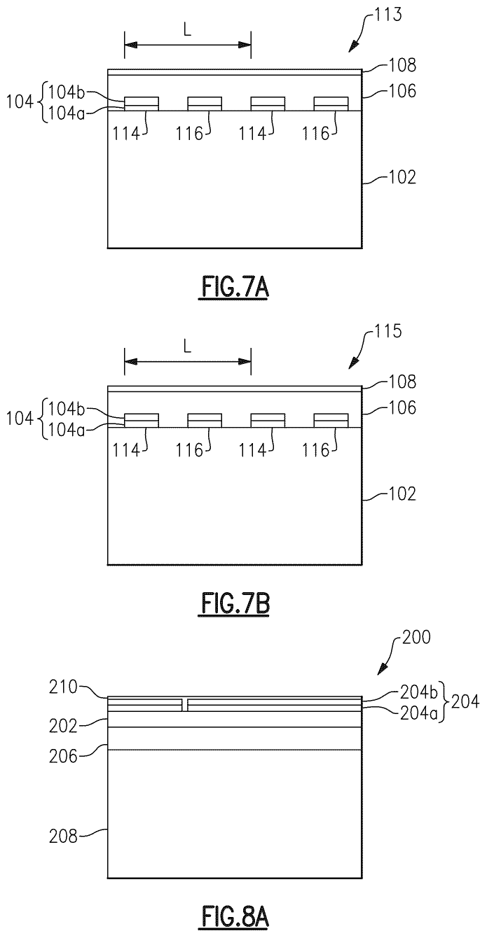

FIG. 10 is a schematic block diagram of a module 301 that includes a power amplifier 306, a radio frequency switch 308, and duplexers 302A to 302N. The power amplifier 306 can amplify a radio frequency signal. The radio frequency switch 308 can be a multi-throw radio frequency switch. The radio frequency switch 308 can electrically couple an output of the power amplifier 132 to a selected transmit filter TX₁-TX_{N} of the duplexers 302A to 101 N. Any suitable numbers of duplexers can be implemented. One or more of the duplexers 302A to 302N can include a transmit filter TX₁-TX_{N} and a receive filter RX₁-RX_{N} in accordance with any suitable principles and advantages discussed herein.

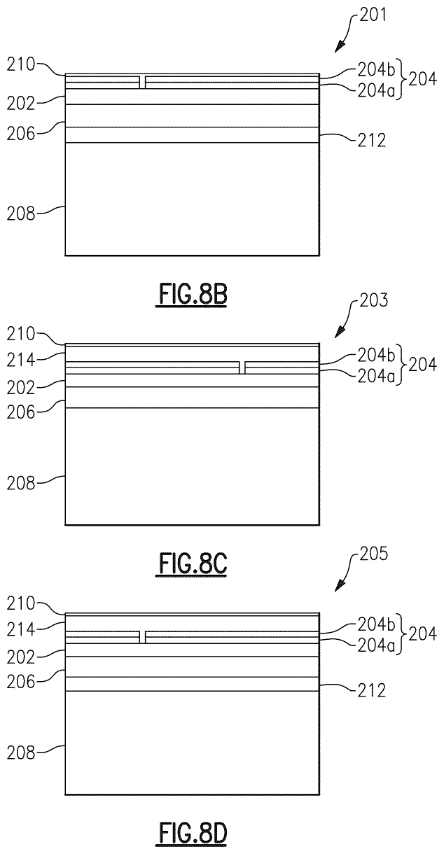

FIG. 11 is a schematic block diagram of a module 303 that includes a power amplifier 306, a radio frequency switch 308, a duplexer 302 and an antenna switch 304. The module 303 can include elements of the module 300 of FIG. 9 and elements of the module 301 of FIG. 10.

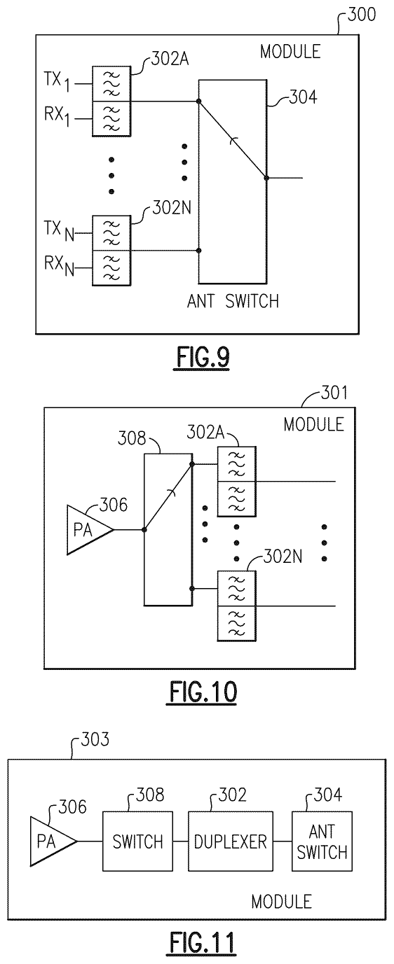

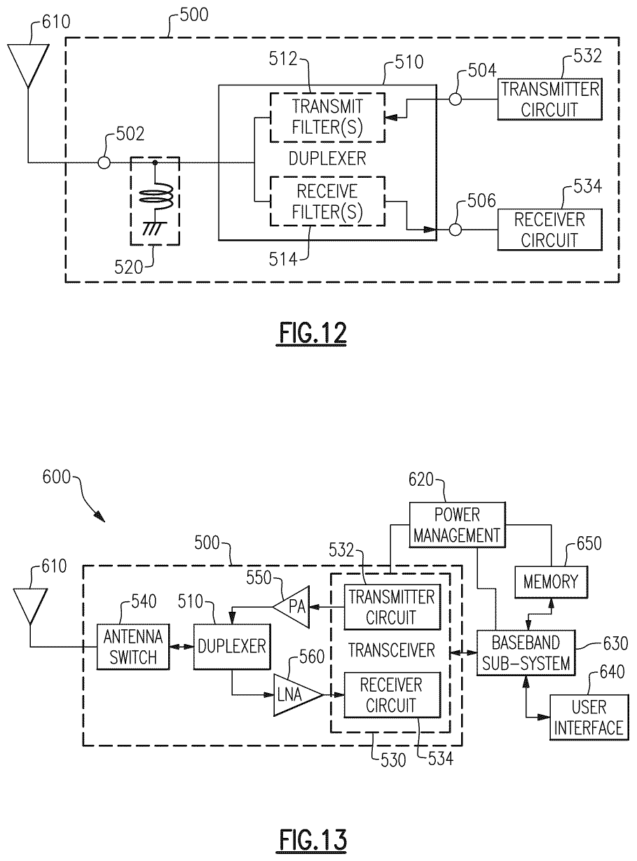

The acoustic wave filters, duplexers, and multiplexers and packaged modules discussed herein can be implemented in a variety of electronic devices, such as radio frequency (RF) front-end modules and wireless communication devices, as illustrated in FIGS. 12 and 13.

Referring to FIG. 12, there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmit filters 512 connected between the input node 504 and the common node 502, and one or more receive filters 514 connected between the common node 502 and the output node 506. The passband(s) of the transmit filter(s) may be different from the passband(s) of the receive filters. Examples of the transmit filter(s) 512 and receive filter(s) 514 can be in accordance with any suitable principles and advantages discussed herein. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver 534 and transmitter 532 circuits are implemented as separate components, as shown in FIG. 12. However, in other embodiments, these components may be integrated into a common transceiver circuit or module. As will be appreciated by those skilled in the art, the front-end module 500 may include other components that are not illustrated in FIG. 12 including, but not limited to, switches, electromagnetic couplers, amplifiers, processors, and the like.

FIG. 13 is a block diagram of one example of a wireless device 600 including the antenna duplexer 510 shown in FIG. 12. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 12. The front-end module 500 includes the duplexer 510, as discussed above. In the example shown in FIG. 13 the front-end module 500 further includes an antenna switch 540, which can be configured to switch between different frequency bands or modes, such as transmit and receive modes, for example. In the example illustrated in FIG. 13, the antenna switch 540 is positioned between the duplexer 510 and the antenna 610. However, in other examples the duplexer 510 can be positioned between the antenna switch 540 and the antenna 610. In other examples, the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 12.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 13, the front-end module 500 may further include a low noise amplifier (LNA) module 560, which amplifies received signals from the antenna 610 and provides the amplified signals to the receiver circuit 534 of the transceiver 530.

The wireless device 600 of FIG. 13 further includes a power management sub-system 620 that is connected to the transceiver 530 and manages the power for the operation of the wireless device 600. The power management system 620 can also control the operation of a baseband sub-system 630 and various other components of the wireless device 600. The power management system 620 can include, or can be connected to, a battery (not shown) that supplies power for the various components of the wireless device 600. The power management system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 500 MHz to 3 GHz.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. An acoustic wave device comprising:
a transmit filter including a first plurality of surface acoustic wave resonators, at least a portion of the first plurality of surface acoustic wave resonators including a first interdigital transducer electrode comprising a first material; and
a receive filter including a second plurality of surface acoustic wave resonators, at least a proportion of the second plurality of surface acoustic wave resonators including a second interdigital transducer electrode comprising a second material, a density of the first material being greater than a density of the second material.

2. The acoustic wave device of claim 1 wherein the receive filter comprises a multi-mode surface acoustic wave filter including a third plurality of surface acoustic wave resonators, at least a portion of the third plurality of surface acoustic wave resonators including a third interdigital transducer electrode comprising the second material.

3. The acoustic wave device of claim 1 wherein the density of the first material is greater than 12.1 g/cm³.

4. The acoustic wave device of claim 1 wherein the density of the first material is greater than 18.0 g/cm³.

5. The acoustic wave device of claim 1 wherein the first material is selected from one or more of platinum, iridium, gold and tungsten.

6. The acoustic wave device of claim 5 wherein the second material is selected from one or more of molybdenum, silver, copper and ruthenium.

7. The acoustic wave device of claim 1 wherein each of the first plurality of surface acoustic wave resonators of the transmit filter includes a multilayer interdigital transducer electrode comprising a first layer of the first material and a second layer comprising a third material.

8. The acoustic wave device of claim 7 wherein the third material is aluminium.

9. The acoustic wave device of claim 1 wherein at least a proportion of the second plurality of surface acoustic wave resonators of the receive filter include a multilayer interdigital transducer electrode comprising a first layer of the second material and a second layer comprising a fourth material.

10. The acoustic wave device of claim 9 wherein the fourth material is aluminum.

11. The acoustic wave device of claim 1 further comprising a low velocity layer disposed between a support substrate and a piezoelectric layer, the low velocity layer having an acoustic velocity lower than an acoustic velocity of the piezoelectric layer.

12. The acoustic wave device of claim 1 wherein the first plurality of surface acoustic wave resonators of the transmit filter are arranged on a first die and the second plurality of surface acoustic wave resonators of the receive filter are arranged on a second die.

13. The acoustic wave device of claim 1 wherein the first interdigital transducer electrode having the first material is arranged on a first die and the second interdigital transducer electrode having the second material is arranged on a second die.

14. The acoustic wave device of claim 1 wherein the first and second plurality of surface acoustic wave resonators are arranged on a same die.

15. A filter assembly comprising:
a plurality of transmit filters, each of the plurality of transmit filters including a first plurality of surface acoustic wave resonators, each of the first plurality of surface acoustic wave resonators including at least a first interdigital transducer electrode comprising a first material; and
a plurality of receive filters, each of the plurality of receive filters including a second plurality of surface acoustic wave resonators, at least a proportion of the second plurality of surface acoustic wave resonators of each receive filter including at least a second interdigital transducer electrode comprising a second material, a density of the first material being greater than a density of the second material.

16. The filter assembly of claim 15 wherein the plurality of transmit filters are co-packaged on a first die and the plurality of receive filters are co-packaged on a second die.

17. The filter assembly of claim 15 wherein the first plurality of surface acoustic wave resonators having the first interdigital transducer electrode of the first material are arranged on a first die and the second plurality of surface acoustic wave resonators having the second interdigital transducer electrode of the second material are arranged on a second die.

18. The filter assembly of claim 15 wherein the plurality of transmit filters and the plurality of receive filters are co-packaged on a same die.

19. The filter assembly of claim 15 wherein the first material is selected from one or more of platinum, iridium, gold and tungsten.

20. The filter assembly of claim 19 wherein the second material is selected from one or more of molybdenum, silver, copper and ruthenium.
